(19) United States
(12) Patent Application Publication
(10) Pub. No.: US 2024/0258227 A1
(43) Pub. Date: Aug. 1, 2024

(54) CHIP ON FILMS AND DISPLAY DEVICES

(71) Applicant: WUHAN CHINA STAR OPTOELECTRONICS SEMICONDUCTOR DISPLAY TECHNOLOGY CO., LTD., Wuhan (CN)

(72) Inventors: Jiajie WANG, Wuhan (CN); Xiaomin WU, Wuhan (CN); Yingchuan JIANG, Wuhan (CN); Wenxu XIANYU, Wuhan (CN)

(21) Appl. No.: 18/474,859

(22) Filed: Sep. 26, 2023

(30) Foreign Application Priority Data
Jan. 31, 2023 (CN) 202310099685.9

(51) Int. Cl. H01L 23/498; H01L 23/13

(52) U.S. Cl. CPC H01L 23/49838; H01L 23/13

(57) ABSTRACT

Display devices and chip on films are provided. The chip on film includes a display bonding area corresponding to bonding positions of a display panel, and includes a base and bonding terminals disposed on the base. In the display bonding area, the base includes first and second bonding portions, which are provided with the bonding terminals thereon. The first bonding portion has an outer contour and includes one part of outer edges of the base. The second bonding portion includes one or more first sub-portions including the other part of the outer edges of the base, and the first sub-portions are concave and/or convex relative to the outer contour; and/or the base further includes one or more hollow portions, the second bonding portion includes one or more second sub-portions, and each of the second sub-portions includes inner edges of the base surrounding one of the hollow portions.

### CROSS-REFERENCE TO RELATED APPLICATION

This application claims priority to Chinese Patent Application No. 202310099685.9, filed on Jan. 31, 2023, the disclosure of which is incorporated herein by reference in its entirety.

### TECHNICAL FIELD

The present disclosure relates to the field of display technologies, and in particular, to chip on films and display devices.

### BACKGROUND

In order to reduce a border of an existing display device, a chip on film (COF) is arranged on a back of a display panel, and terminals on the display panel are arranged on the back to bond the COF, so as to realize a normal operation of the display device. However, due to the limitation of a manufacturing process of conductive wirings, terminals can only be arranged along edges of the COF, resulting in a relatively dense arrangement of the terminals. When the terminals on the COF are bonded to the terminals on the display panel, a distance between conductive adhesives which bonding the terminals on the COF and the terminals on the display panel is small, and short circuits may occur. In addition, the COF needs to be designed separately, and it is necessary to reduce a size of the COF as much as possible to reduce the capacity occupied by the COF, but this will further reduce the distance between the conductive adhesives, which may increase the difficulty of preparing the conductive adhesives and increase the possibility of short circuits.

Therefore, the existing display devices have the technical problem that short circuits are prone to occur between the conductive adhesives due to a small space for arranging the terminals on the COF.

### SUMMARY

In view of above, chip on films are provided according to embodiments of the present disclosure. The chip on film includes a display bonding area corresponding to bonding positions of a display panel. The COF includes a base and bonding terminals disposed on a side of the base. In the display bonding area, the base includes a first bonding portion and a second bonding portion, and both of the first bonding portion and the second bonding portion are provided with the bonding terminals thereon. The first bonding portion has an outer contour and includes one part of outer edges of the base. The second bonding portion includes one or more first sub-portions, the first sub-portions includes the other part of the outer edges of the base, and the first sub-portions are concave and/or convex relative to the outer contour of the first bonding portion; and/or the base further includes one or more hollow portions, the second bonding portion includes one or more second sub-portions, and each of the second sub-portions includes inner edges of the base surrounding one of the hollow portions.

Display devices are further provided according to embodiments of the present disclosure. The display device includes a display panel, the above chip on film, and conductive adhesives; the display panel includes a substrate and a driving circuit layer disposed on a side of the substrate, and includes signal terminals; the chip on film is arranged on a side of the substrate away from the driving circuit layer; and the conductive adhesive connects the signal terminal and the bonding terminal.

### BRIEF DESCRIPTION OF THE DRAWINGS

The technical solutions and other beneficial effects of the present disclosure will be apparent through the detailed description of specific embodiments of the present disclosure below in conjunction with the accompanying drawings.

FIG. 1 is a schematic view of a display device in related art.

FIG. 2 is a first schematic view of a COF provided according to embodiments of the present disclosure.

FIG. 3 is a second schematic view of a COF provided according to embodiments of the present disclosure.

FIG. 4 is a third schematic view of a COF provided according to embodiments of the present disclosure.

FIG. 5 is a fourth schematic view of a COF provided according to embodiments of the present disclosure.

FIG. 6 is a fifth schematic view of a COF provided according to embodiments of the present disclosure.

FIG. 7 is a first schematic view of a display device provided according to embodiments of the present disclosure.

FIG. 8 is a second schematic view of a display device provided according to embodiments of the present disclosure.

FIG. 9 is a schematic view of a same mask used by the display panel and the COF provided according to embodiments of the present disclosure.

### DETAILED DESCRIPTION

The following will clearly and completely describe the technical solutions in the embodiments of the present disclosure with reference to the drawings in the embodiments of the present disclosure. Obviously, the described embodiments are only some of the embodiments of the present disclosure, not all of them. Based on the embodiments in the present disclosure, all other embodiments obtained by those skilled in the art without creative efforts fall within the protection scope of the present disclosure.

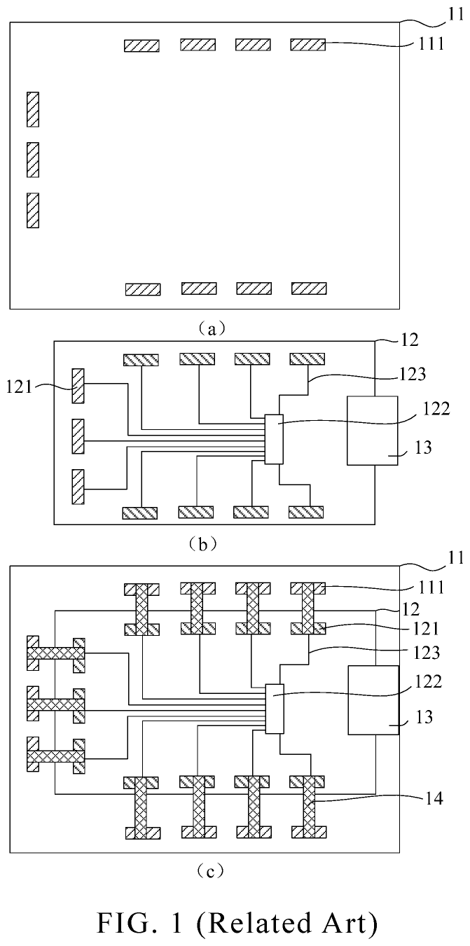

As illustrated in FIG. 1, the COF of an existing display device is bonded by pressing, in view of a problem that wirings located inside the existing display device may be damaged during the pressing process, a back bonding technology is proposed to bond the COF of the display device in related art. Specifically, first terminals 111 are exposed on the back of a display panel 11 of the display device in the related art, and then a COF 12 is bonded to the back of the display panel 11. As illustrated in part (b) of FIG. 1, due to the limitation of the manufacturing process of conductive wirings, second terminals 121 can only be arranged on edges of the COF 12. One edge of the COF 12 needs to be reserved for bonding a flexible circuit board 13, so the second terminals 121 can only be arranged on the other three edges of the COF 12, and then the second terminals 121 are connected to a chip 122 through signal lines 123. Correspondingly, as illustrated in part (a) of FIG. 1, the first terminals 111 are distributed on edges of the display panel 11. As illustrated in part (c) of FIG. 1, when the COF 12 is bonded to the display panel 11, conductive adhesives 14 are used to bond the first terminals 111 and the second terminals 121. However, since the second terminals 121 are densely arranged and a distance between adjacent conductive adhesives 14 is small, short circuits may occur; and since the COF needs to be designed separately, and a size of the COF is expected to be as small as possible to reduce the capacity occupied by the COF, but this will further reduce the distance between the conductive adhesives, which may increase the difficulty of preparing the conductive adhesives and increase the possibility of short circuits. Therefore, the existing display devices have the technical problem that short circuits are prone to occur between the conductive adhesives due to a small space for arranging the terminals on the COF.

Embodiments of the present disclosure aim at the above-mentioned technical problem, and provide COFs and display devices to relieve the above-mentioned technical problem.

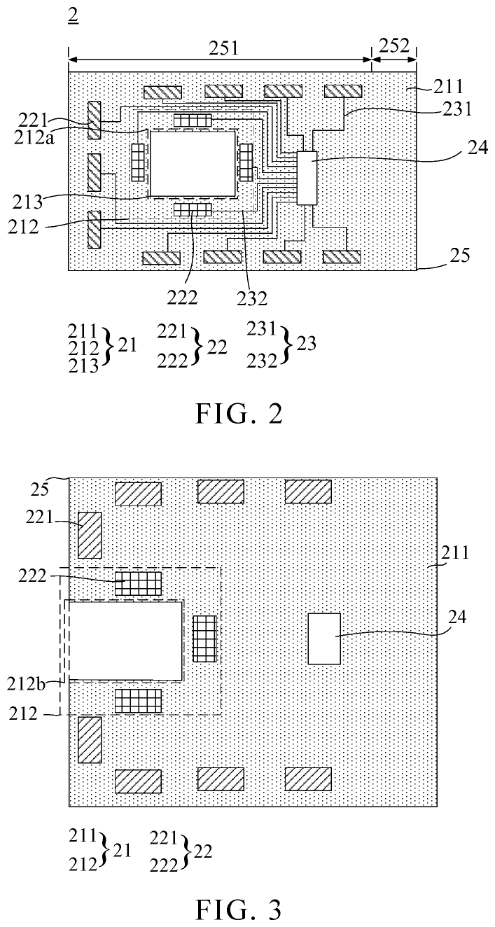

As illustrated in FIG. 2 to FIG. 4, embodiments of the present disclosure provide chip on films. The COF 2 includes a display bonding area 251 corresponding to bonding positions of the display panel. The COF 2 includes a base 21 and bonding terminals 22 disposed on a side of the base 21. In the display bonding area 251, the base 21 includes a first bonding portion 211 and a second bonding portion 212, and both of the first bonding portion 211 and the second bonding portion 212 are provided with the bonding terminals 22 thereon. The first bonding portion 211 has an outer contour 25 and includes one part of outer edges of the base 21.

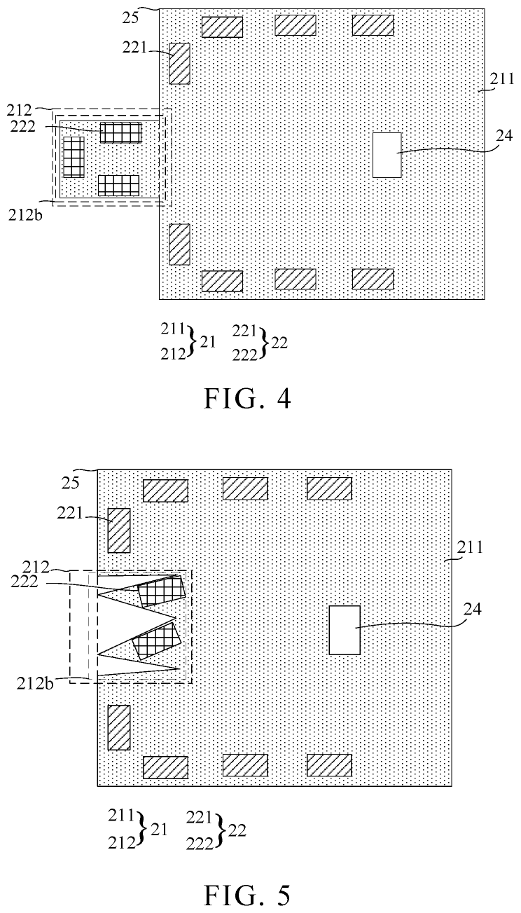

The second bonding portion 212 includes one or more first sub-portions 212b, and the first sub-portions 212b include the other part of the outer edges of the base 21, the first sub-portions 212b are concave (as illustrated in FIG. 3) and/or convex (as illustrated in FIG. 4) relative to the outer contour 25 of the first bonding portion 211; and/or
the base 21 further includes one or more hollow portions 213, the second bonding portion 212 includes one or more second sub-portions 212a, and the second sub-portion 212a includes inner edges (as illustrated in FIG. 2) of the base 21 surrounding the hollow portion 213.

Embodiments of the present disclosure provide chip on films. In the chip on films, the base includes the first bonding portion and the second bonding portion, and the first sub-portions of the second bonding portion are concave and/or convex relative to the outer contour of the first bonding portion, so that the space on the outer edges of the base for arranging the bonding terminals may be increased; and/or the hollow portions are provided, and the second sub-portion of the second bonding portion includes the inner edges of the base surrounding the hollow portion, so that the space on the inner edges of the base for arranging the bonding terminals is increased. Therefore, the space for arranging the bonding terminals on the base may be increased, so that on the basis of ensuring the size of the COF, a distance between the bonding terminals may be increased, which correspondingly increase the distance between the conductive adhesives to avoid short circuits. In addition, on the basis of ensuring the distance between the bonding terminals, the size of the COF may be reduced, so that the COF and the display panel may be prepared by using a same mask, which improves the manufacturing efficiency of the display device and reduces the costs.

It should be noted that the outer contour of the first bonding portion refers to an outermost frame surrounding the first bonding portion. Specifically, as illustrated in FIG. 2, the outermost frame of the first bonding portion 211 may be a regular rectangle, the outer contour of the first bonding portion is a rectangular frame. As illustrated in FIG. 3, when there is a depression on the outer edge of the first bonding portion 211, the outermost frame surrounding the first bonding portion is still rectangle, the outer contour of the first bonding portion is still a rectangular frame. Similarly, for the designs in FIG. 4 to FIG. 6, the outer contour of the first bonding portion is still a rectangular frame.

It should be noted that the base includes the first bonding portion, the second bonding portion, and the hollow portions, but in an actual preparation process, the first bonding portion, the second bonding portion, and the hollow portions are integrally arranged, and there are no boundaries or splicing lines. The first bonding portion of the base may extend to a circuit board bonding area 252, so all parts other than the second bonding portion 212 of the base 21 are labeled as the first bonding portion 211 in FIG. 2.

Specifically, in the existing display devices, the distance between the conductive adhesive is increased by increasing the size of the COF; alternatively, the size of COF is reduced by reducing a number of the bonding terminals or reducing the distance between adjacent bonding terminals. Compared with the existing display devices, in the embodiments of the present disclosure, the distance between the conductive adhesives is increased by increasing the space for arranging the bonding terminals, so as to avoid short circuits between the conductive adhesives and reduce the size of the COF at the same time, which does not need to reduce the number of the bonding terminals or reduce the distance between the adjacent bonding terminals, so that increasing the distance between the conductive adhesives and reducing the size of the COF may be reached at the same time, and the resolution of the display device may be improved by increasing the number of bonding terminals.

In an embodiment, as illustrated in FIG. 3, the second bonding portion 212 includes at least one first sub-portion 212b, and the first sub-portion 212b is concave relative to the outer contour 25 of the first bonding portion 211 to form a groove. Some of the bonding terminals 22 are disposed on the second bonding portion 212 along edges defining the groove. In this embodiment, since the second bonding portion includes the first sub-portions, and the first sub-portion includes the groove, so that concave grooves are formed on the base, and the space for arranging the bonding terminals on the edges of the base increases, which may reduce the size of the COF while ensuring or increasing the distance between the bonding terminals, so that increasing the distance between the conductive adhesives and reducing the size of the COF may be reached at the same time.

Specifically, as illustrated in FIG. 3, the bonding terminals are provided on three sides of the groove in the first sub-portion. Compared with a single linear edge of the base in the related art, in which the bonding terminals are arranged only on one edge, the groove design in the embodiments of the present disclosure provides three edges for arranging the bonding terminals, which may increase the space for arranging the bonding terminals, thereby increasing the distance between the bonding terminals, increasing the distance between the conductive adhesives, avoiding short circuits caused by too small distance between the conductive adhesives, and improving the yield of the display device. Furthermore, the size of the COF may be reduced while ensuring the distance between the bonding terminals, so that the COF and the display panel may be prepared by using the same mask, which improves the manufacturing efficiency of the display device and reducing the costs.

In an embodiment, the second bonding portion includes a plurality of first sub-portions. The plurality of first sub-portions include grooves with at least two different opening directions, and there is a distance between projections of two grooves respectively located on adjacent edges of the first bonding portion on either edge of the first bonding portion. Since the grooves are arranged on at least two edges of the first bonding portion, so that the space for arranging the bonding terminals on the base may be further increased. Since there is a distance between projections of the grooves located on adjacent edges of the first bonding portion on either edge of the first bonding portion, so that a contact between the grooves on the edges of the base may be avoided, where the contact between the grooves may result in the inability to arrange the bonding terminals or the problem of small space for arranging the bonding terminals. Therefore, the space for arranging the bonding terminals is further increased, thereby improving the distance between the bonding terminals, ensuring or improving the distance between conductive adhesives, and reducing the size of COF, which makes the COF and the display panel be prepared by using the same mask to improve the manufacturing efficiency of the display device and reduce the costs.

Specifically, the above embodiment has been described in detail by taking the grooves arranged on at least two edges of the first bonding portion as an example, but the embodiments of the present disclosure are not limited thereto. For example, the grooves may be arranged on three edges of the first bonding portion. Meanwhile, it can be understood that, for other designs of the second bonding portion, for example, when the second bonding portion includes protrusions, the protrusions may also be arranged on multiple edges of the first bonding portion.

In an embodiment, each side of the groove is provided with the bonding terminal, or along a direction perpendicular to a connecting line of the bonding terminals on opposite sides of the groove, multiple bonding terminals are provided on each of the opposite sides of the groove. By arranging the bonding terminal on each side of the groove, or arranging multiple bonding terminals on each of the opposite sides of the groove, the bonding terminals are arranged on the sides of the groove, which may increase the space for arranging the bonding terminal, reduce a number of the bonding terminals on the first bonding portion, and increase the distance between the bonding terminals. Therefore, the distance between the bonding terminals is still large while the size of COF is reduced, so as to avoid short circuits of the conductive adhesives and improve the yield of the display device.

Specifically, as illustrated in FIG. 3, it can be seen that the three sides of the groove are provided with second bonding terminals 222 thereon. Since the COF of the existing display device is not provided with the groove, only one bonding terminal may be arranged in an area corresponding the groove, and the three sides of the groove in the present disclosure are provided with the bonding terminals, so that the space for arranging the bonding terminals in the COF increases. Multiple bonding terminals are arranged on each of the opposite sides of the groove, so the number of the bonding terminals arranged on the first bonding portion may be reduced, which may increase the distance between the bonding terminals, thereby avoiding short circuits of the conductive adhesives and improving the yield of the display device.

Specifically, when arranging the second bonding terminals, a width of the groove may be greater than a length of the bonding terminal, so that the bonding terminal may be arranged horizontally or vertically, thereby increasing the space for arranging the bonding terminals and increasing the distance between the bonding terminals, which may avoid the short circuits of the conductive adhesives and improve the yield of the display device.

Specifically, when arranging the bonding terminals, multiple bonding terminals may be provided on one side of the groove, which may reduce the number of the bonding terminals arranged on the first bonding portion and increase the distance between the bonding terminals, thereby avoiding the short circuits of the conductive adhesive and improving the yield of the display device.

In an embodiment, the second bonding portions may include at least two grooves on one edge of the first bonding portion, and a distance between adjacent grooves is greater than a width of the bonding terminal. By arranging at least two grooves on one edge of the first bonding portion, the space for arranging the bonding terminal may be further increased. By making the distance between adjacent grooves greater than the width of the bonding terminal, the bonding terminals may be arranged between adjacent grooves, which further increases the space for arranging the bonding terminals. Therefore, the distance between the bonding terminals may be increased, thereby avoiding the short circuits of the conductive adhesives, improving the yield of the display device, and reducing the size of COF while ensuring or improving the distance between the bonding terminals.

Specifically, the above embodiment is described by taking at least two grooves disposed on one edge of the first bonding portion as an example. It can be understood that a plurality of grooves may be provided on one edge of the first bonding portion, for example, three grooves may be provided on one edge of the first bonding portion. Meanwhile, it can be understood that, for the design that the second bonding portion includes protrusions or other structures, multiple protrusions or other structures may be provided on one edge of the first bonding portion.

In an embodiment, as illustrated in FIG. 4, the first sub-portion 212b is convex relative to the outer contour 25 of the first bonding section 211 to form a protrusion, and some of the bonding terminals 22 are disposed on the second bonding portion 212 along edges of the protrusion. By making the second bonding portions include protrusions, the base is formed with protrusions, the space for arranging the bonding terminals on the edges of the base increases, thereby reducing the size of the COF while ensuring or increasing the distance between the bonding terminals, so that increasing the distance between the conductive adhesives and reducing the size of the COF may be reached at the same time.

Specifically, each edge of the protrusion is provided with the bonding terminal, or along a direction perpendicular to a connecting line of the bonding terminals on opposite edges of the protrusion, multiple bonding terminals are provided on each of the opposite edges of the protrusion.

Specifically, as illustrated in FIG. 4, it can be seen that the three edges of the protrusion are provided with the second bonding terminals 222. Since the COF of the existing display device is not provided with the protrusion, only one bonding terminal may be arranged in an area corresponding the protrusion, and the three edges of the protrusion in the present disclosure are provided with the bonding terminals, so that the space for arranging the bonding terminals in the COF increases. Multiple bonding terminals are arranged on each of the opposite edges of the protrusion, so the number of the bonding terminals arranged on the first bonding portion may be reduced, which may increase the distance between the bonding terminals, thereby avoiding short circuits of the conductive adhesives and improving the yield of the display device.

Specifically, when arranging the bonding terminals on the second bonding portion, a width of the protrusion may be greater than a length of the bonding terminal, so that the bonding terminal may be arranged horizontally or vertically, thereby increasing the space for arranging the bonding terminals and increasing the distance between the bonding terminals, which may avoid the short circuits of the conductive adhesives and improve the yield of the display device.

Specifically, when arranging the bonding terminals, multiple bonding terminals may be provided on one edge of the protrusion, which may reduce the number of the bonding terminals arranged on the first bonding portion and increase the distance between the bonding terminals, thereby avoiding the short circuits of the conductive adhesive and improving the yield of the display device.

In an embodiment, as illustrated in FIG. 5, some or all of the first sub-portions 212b each have a zigzag-shape corresponding to the edge of the base 21, and some of the bonding terminals 22 are disposed on the second bonding portion 212 corresponding to zigzag-shaped edges of the base. By making some or all of the first sub-portions each have a zigzag-shape corresponding to the edge of the base, irregular edges are formed on the base, which increases the space for arranging the bonding terminals on the edges of the base, thereby reducing the size of the COF while ensuring or increasing the distance between the bonding terminals, so that increasing the distance between the conductive adhesives and reducing the size of the COF may be reached at the same time.

Specifically, the zigzag-shaped first sub-portion may be located within the outer contour of the first bonding portion, as illustrated in FIG. 5; or the zigzag-shaped first sub-portion may also be located outside the outer contour of the first bonding portion; or the zigzag-shaped first sub-portion may have one part inside the outer contour of the first bonding portion and the other part outside the outer contour of the first bonding portion.

Specifically, edges of each tooth of the zigzag-shaped first sub-portion is provided with the bonding terminal; or multiple bonding terminals are provided on each tooth of the zigzag-shaped first sub-portion. By arranging the bonding terminal on the edges of each tooth of the zigzag-shaped first sub-portion, or arranging multiple bonding terminals on each tooth of the zigzag-shaped first sub-portion, the bonding terminals may be arranged in the edges of the zigzag-shaped second bonding portion, which may increase the space for arranging the bonding terminals, reduce a number of the bonding terminals on the first bonding portion, and increase the distance between the bonding terminals. Therefore, the distance between the bonding terminals is still large while the size of COF is reduced, so as to avoid short circuits of the conductive adhesives and improve the yield of the display device.

Specifically, as illustrated in FIG. 5, it can be seen that the two teeth of the zigzag-shaped first sub-portion 212b are both provided with the second bonding terminals 222. The COF of the existing display device is not provided with the zigzag-shaped first sub-portion, and only one bonding terminal may be arranged in an area corresponding the zigzag-shaped first sub-portion, compared with the related art, the embodiments of the present disclosure provide the zigzag-shaped first sub-portions in the base, and each tooth of the zigzag-shaped first sub-portions is provided with the bonding terminal, so that the space for arranging the bonding terminals in the COF increases. Multiple bonding terminals are arranged on the edges of the tooth, so the number of the bonding terminals arranged on a main body may be reduced, which may increase the distance between the bonding terminals, thereby avoiding short circuits of the conductive adhesives and improving the yield of the display device.

Specifically, when arranging the bonding terminals, a width of the zigzag-shaped first sub-portion is greater than the length of the bonding terminal, so that the first sub-portion may be arranged horizontally, thereby increasing the space for arranging the bonding terminals and increasing the distance between the bonding terminals, which may avoid the short circuits of the conductive adhesives and improve the yield of the display device.

In an embodiment, the plurality of first sub-portions include protrusions convex relative to the outer contour of the first bonding portion and depressions concave relative to the outer contour of the first bonding portion. By making the second bonding portion include the protrusions convex relative to the outer contour of the first bonding portion and the depressions concave relative to the outer contour of the first bonding portion, the space for arranging the bonding terminals on the edges of the base increases through the protrusions and the depressions, thereby reducing the size of the COF while ensuring or increasing the distance between the bonding terminals, thus the distance between the conductive adhesives and the size of the COF may be taken into account.

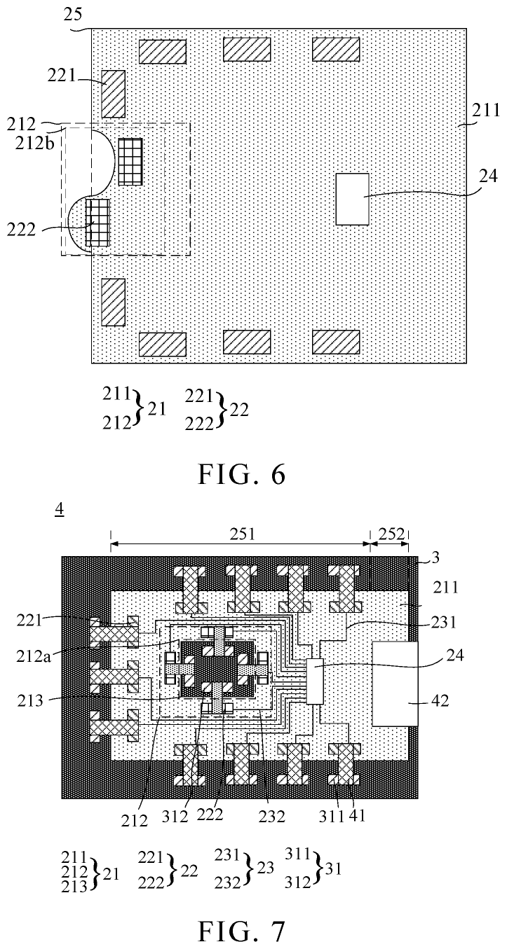

In an embodiment, as illustrated in FIG. 6, the plurality of first sub-portions 212b include a plurality of protrusions convex relative to the outer contour of the first bonding portion and a plurality of depressions concave relative to the outer contour of the first bonding portion. The plurality of protrusions and the plurality of depressions are alternately arranged and connected along the outer contour 25 of the first bonding portion 211, and a shape of outer edges of the plurality of first sub-portions 212b is wavy. By making the plurality of first sub-portions 212b include the protrusions and the depressions and by connecting the above two parts, the outer edges of the plurality of first sub-portions 212b are wave-shaped, so that the bonding terminals may be arranged on the wave-shaped edges of the second bonding portion, which increases the space for arranging the bonding terminals on the edges of the base, thereby reducing the size of the COF while ensuring or increasing the distance between the bonding terminals, thus the distance between the conductive adhesives and the size of the COF may be taken into account.

There may be a technical problem that the distance between the bonding terminals is still small resulting in short circuits of the conductive adhesives when the second bonding portion disposed on the edges of the base. Aiming at the technical problem, in an embodiment, as illustrated in FIG. 2, the hollow portion 213 is provided with a through hole, and the second sub-portion 212a is arranged around the through hole. Some of the bonding terminals 22 are arranged around the edge defining the through hole on the second sub-portion 212a, the first bonding portion 211 is arranged around the second sub-portion 212a, and some of the bonding terminals 22 are arranged on a side of the first bonding portion 211 away from the second sub-portion 212a. By forming the through hole on the base, the through hole may expose the terminals on the display panel to realize the connection between the display panel and the COF. When arranging the bonding terminals, some of them may be arranged around the through hole, thereby increasing the space for arranging the bonding terminals and increasing the distance between the bonding terminals. Therefore, the distance between the bonding terminals is still relatively large when the size of the COF is reduced, which may avoid the short circuits of the conductive adhesives and improve the yield of the display device.

Specifically, the bonding terminals may be arranged on one or more sides of the through hole, so that the number of the bonding terminals located on the first bonding portion may be reduced, and the distance between the bonding terminals may be increased. Therefore, the distance between the bonding terminals is still relatively large when the size of the COF is reduced, which may avoid the short circuits of the conductive adhesives and improve the yield of the display device.

In an embodiment, the hollow portions include a plurality of through holes, the second bonding portion includes a plurality of second sub-portions each arranged around one of the through holes. Some of the bonding terminals are arranged around the edges defining the through hole on the second sub-portion, the first bonding portion is arranged around the second sub-portions, and some of the bonding terminals are arranged on sides of the first bonding portion away from the second sub-portions. By making the hollow portions include the plurality of through holes, the space for arranging the bonding terminals may be further increased, and the distance between the bonding terminals may be increased accordingly. Therefore, the distance between the bonding terminals is still relatively large when the size of the COF is reduced, which may avoid the short circuits of the conductive adhesives and improve the yield of the display device.

In an embodiment, a distance between two adjacent through holes is at least greater than a width of two bonding terminals, so that multiple bonding terminals may be arranged between two adjacent through holes, thereby further increasing the space for arranging the bonding terminals and correspondingly increasing the distance between the bonding terminals. Therefore, the distance between the bonding terminals is still relatively large when the size of the COF is reduced, which may avoid the short circuits of the conductive adhesives and improve the yield of the display device.

In an embodiment, as illustrated in FIG. 2, the bonding terminals 22 include first bonding terminals 221 and the second bonding terminals 222. The first bonding terminals 221 are arranged on the first bonding portion 211, and the second bonding terminals 222 are arranged on the second bonding portion 212. There is a distance between the first bonding terminal 221 and the second bonding terminal 222, so that a contact between the first bonding terminal and the second bonding terminal is avoided to prevent short circuits between the bonding terminals.

Specifically, the second bonding terminals 222 are arranged around the through holes, and there is a distance between the second bonding terminal 222 and the first bonding terminal 221. By arranging the second bonding terminals around the through hole, the number of the first bonding terminals located on the first bonding portion may be reduced, the distance between the first bonding terminals may be increased, the short circuits of the conductive adhesive may be avoided, and the yield of the display device may be improved.

It should be noted that the first bonding terminals and the second bonding terminals are used to illustrate the arrangement of the bonding terminals on the first bonding portion and the second bonding portion. Shapes and structures of the first bonding terminals and the second bonding terminals are not limited, and only positions of the bonding terminals are defined, where the bonding terminals located on the first bonding portion are the first bonding terminals, and the bonding terminals located on the second bonding portion are the second bonding terminals.

When the terminals on the COF and the terminals on the display panel are connected by the conductive adhesives, there may be a problem of short circuits between the conductive adhesives and the signal wirings. In an embodiment, as illustrated in FIG. 2, the COF 2 further includes signal wirings 23 and a driving chip 24. The signal wirings 23 are disposed between the base 21 and the bonding terminals 22, and an end of the signal wiring 23 is connected to the bonding terminal 22. The driving chip 24 is arranged on a side of the signal wirings 23 away from the base 21, and the driving chip 24 is connected to the other end of each of the signal wirings 23.

The signal wirings 23 include first signal wirings 231 and second signal wirings 232. The first signal wiring 231 is connected to the first bonding terminal 221, and the second signal wiring 232 is connected to the second bonding terminal 222. The first signal wirings 231 are disposed on sides of the second signal wirings 232 away from the second bonding terminals 222, so that a short circuit due to an intersection of the conductive adhesive and the signal wiring will be avoided, which improves the yield of display device.

In an embodiment, as illustrated in FIG. 2, the COF 2 further includes the circuit board bonding area 252 corresponding to a position for bonding a flexible circuit board.

Meanwhile, embodiments of the present disclosure provide display devices. The display device includes the COF as described in any one of the above-mentioned embodiments.

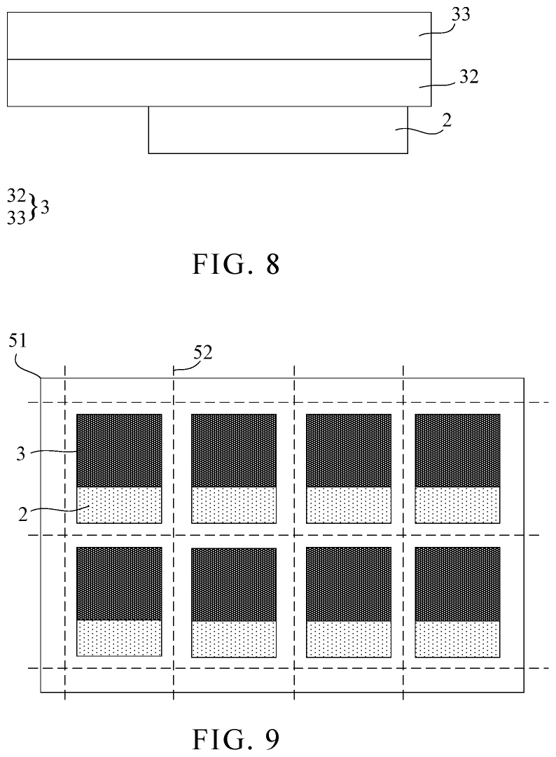

As illustrated in FIG. 2 to FIG. 4, FIG. 7, and FIG. 8, embodiments of the present disclosure provide the display devices, and the display device 4 includes a display panel 3, a COF 2, and conductive adhesives 41.

The display panel 3 includes a substrate 32 and a driving circuit layer 33, the driving circuit layer 33 is arranged on a side of the substrate 32, and the display panel 3 includes signal terminals 31.

The COF 2 is arranged on a side of the substrate 32 away from the driving circuit layer 33. The COF 2 includes the display bonding area 251 corresponding to bonding positions of the display panel. The COF 2 includes the base 21 and the bonding terminals 22 disposed on a side of the base 21. In the display bonding area 251, the base 21 includes the first bonding portion 211 and the second bonding portion 212, and both of the first bonding portion 211 and the second bonding portion 212 are provided with the bonding terminals 22 thereon. The first bonding portion 211 has the outer contour 25 and includes one part of outer edges of the base 21. The second bonding portion 212 includes one or more first sub-portions 212b, the first sub-portions 212b include the other part of the outer edges of the base 21, and the first sub-portions 212b are concave (as illustrated in FIG. 3) and/or convex (as illustrated in FIG. 4) relative to the outer contour 25 of the first bonding portion 211; and/or the base 21 further includes one or more hollow portions 213, the second bonding portion 212 includes one or more second sub-portions 212a, and the second sub-portion 212a includes inner edges (as illustrated in FIG. 2) of the base 21 surrounding the hollow portion 213.

The conductive adhesive 41 connects the signal terminal 31 and the bonding terminal 22.

Embodiments of the present disclosure provide display devices. The display device includes the display panel, the COF, and the conductive adhesives. In the COF, the base includes the first bonding portion and the second bonding portion, and the first sub-portions of the second bonding portion are concave and/or convex relative to the outer contour of the first bonding portion, so that the space on the outer edges of the base for arranging the bonding terminals may be increased; and/or the hollow portions are provided, and the second sub-portion of the second bonding portion includes the inner edges of the base surrounding the hollow portion, so that the space on the inner edges of the base for arranging the bonding terminals is increased. Therefore, the space for arranging the bonding terminals on the base may be increased, so that on the basis of ensuring the size of the COF, a distance between the bonding terminals may be increased, which correspondingly increase the distance between the conductive adhesives to avoid short circuits. In addition, on the basis of ensuring the distance between the bonding terminals, the size of the COF may be reduced, so that the COF and the display panel may be prepared by using a same mask, which improves the manufacturing efficiency of the display device and reduces the costs.

In an embodiment, the display panel includes a display area, a bending area, and a bonding area. An area of the COF is less than or equal to a sum of areas of the bending area and the bonding area. By making the area of the COF less than or equal to the sum of the areas of the bending area and the bonding area, the COF corresponds to the bending area and the bonding area when preparing the display device, thereby the manufacturing efficiency of the display device and reducing the costs.

Specifically, it can be known from the above-mentioned embodiments that the present disclosure may increase the distance between the bonding terminals and reduce the size of the COF. When forming the COF, in the same-sized mask, more COFs may be manufactured. Furthermore, as illustrated in FIG. 9, the display panels 3 and the COFs 2 may be prepared by using the same mask 51, and the display panels 3 and the COFs 2 may be cut through cutting lines to obtain single display panel 3 and single COF 2, which may reduce the costs.

In an embodiment, as illustrated in FIG. 7, the bonding terminals 22 include first bonding terminals 221 and second bonding terminals 222. The first bonding terminals 221 are arranged on the first bonding portion 211, and the second bonding terminals 222 are arranged on the second bonding portion 212.

The signal terminals 31 include first signal terminals 311 and second signal terminals 312. The first signal terminals 311 are arranged along edges of the first bonding portion 211, and the second signal terminals 312 are arranged along edges of the hollow portions 213. When the COF is attached to the display panel 3, the second signal terminals 312 are exposed, so that the signal terminals are connected to the bonding terminals through the conductive adhesives, which may facilitate the connection between the display panel and the COF.

Aiming at the technical problem that the conductive adhesives may be in contact with the signal wirings and cause short circuits to cause signal interference. In an embodiment, the display device further includes insulation glues disposed on sides of the conductive adhesives close to the base, so that even if the conductive adhesive crosses the signal wirings, due to the isolation of the insulation glue, the short circuits between the conductive adhesives and the signal wirings may be avoided.

In an embodiment, the insulation glues are arranged correspondingly to the conductive adhesives, and a width of the insulation glue is greater than a width of the conductive adhesive, so that the conductive adhesive may be isolated, thereby avoiding short circuits between the conductive adhesives and the signal wirings and improving the yield of the display device.

In an embodiment, as illustrated in FIG. 7, the display device 4 further includes a flexible circuit board 42, and the flexible circuit board 42 is connected to the COF.

According to the above embodiments, display devices and COFs are provided. The COF includes a display bonding area corresponding to bonding positions of a display panel. The COF includes a base and bonding terminals disposed on a side of the base. In the display bonding area, the base includes a first bonding portion and a second bonding portion, and both of the first bonding portion and the second bonding portion are provided with the bonding terminals thereon. The first bonding portion has an outer contour and includes one part of outer edges of the base. The second bonding portion includes one or more first sub-portions, the first sub-portions includes the other part of the outer edges of the base, and the first sub-portions are concave and/or convex relative to the outer contour of the first bonding portion; and/or the base further includes one or more hollow portions, the second bonding portion includes one or more second sub-portions, and each of the second sub-portions includes inner edges of the base surrounding one of the hollow portions. In the present disclosure, the base includes the first bonding portion and the second bonding portion, and the first sub-portions of the second bonding portion are concave and/or convex relative to the outer contour of the first bonding portion, so that the space on the outer edges of the base for arranging the bonding terminals may be increased; and/or the hollow portions are provided, and the second sub-portion of the second bonding portion includes the inner edges of the base surrounding the hollow portion, so that the space on the inner edges of the base for arranging the bonding terminals is increased. Therefore, the space for arranging the bonding terminals on the base may be increased, so that on the basis of ensuring the size of the COF, a distance between the bonding terminals may be increased, which correspondingly increase the distance between the conductive adhesives to avoid short circuits. In addition, on the basis of ensuring the distance between the bonding terminals, the size of the COF may be reduced, so that the COF and the display panel may be prepared by using a same mask, which improves the manufacturing efficiency of the display device and reduces the costs.

In the foregoing embodiments, the descriptions of each embodiment have their own emphases, and for parts not described in detail in a certain embodiment, reference may be made to relevant descriptions of other embodiments.

Chip on films and display devices provided by the embodiments of the present disclosure have been described above in detail. In this paper, specific examples are used to illustrate the principles and implementation methods of the present disclosure. The descriptions of the above embodiments are only used to help understand the technical solutions and their core ideas of the present disclosure. Those of ordinary skill in the art should understand that: it is still possible to modify the technical solutions recorded in the foregoing embodiments, or perform equivalent replacements for some of the technical features; however, these modifications or replacements do not make the essence of the corresponding technical solutions depart from the scope of the technical solutions of the embodiments of the present disclosure.

What is claimed is:

1. A chip on film, comprising a display bonding area corresponding to bonding positions of a display panel, and comprising:
a base; and
bonding terminals, disposed on a side of the base,
wherein in the display bonding area, the base comprises a first bonding portion and a second bonding portion, and both of the first bonding portion and the second bonding portion are provided with the bonding terminals thereon;
the first bonding portion has an outer contour and comprises one part of outer edges of the base; and
the second bonding portion comprises one or more first sub-portions, the first sub-portions comprise the other part of the outer edges of the base, and the first sub-portions are concave and/or convex relative to the outer contour of the first bonding portion.

2. The chip on film according to claim 1, wherein the second bonding portion comprises one or more first sub-portions, each of the first sub-portions is concave relative to the outer contour of the first bonding portion to define a groove, and some of the bonding terminals are arranged along one or more sides of the groove on the second bonding portion.

3. The chip on film according to claim 2, wherein the second bonding portion comprises a plurality of first sub-portions, grooves defined by the plurality of first sub-portions have at least two different opening directions, and for two of the grooves respectively located on two adjacent edges of the first bonding portion, there is a distance between projections of them on either edge of the first bonding portion.

4. The chip on film according to claim 2, wherein the second bonding portion comprises a plurality of first sub-portions, two grooves defined by the plurality of first sub-portions are located on a same edge of the first bonding portion, and a distance between adjacent ones of the grooves is greater than a width of each of the bonding terminals.

5. The chip on film according to claim 2, wherein a width of the groove is greater than a length of each of the bonding terminals.

6. The chip on film according to claim 2, wherein the groove is provided with one or more of the bonding terminals on each of opposite sides thereof.

7. The chip on film according to claim 2, wherein some or all of the first sub-portions each has a zigzag-shape corresponding to an edge of the base, and some of the bonding terminals are arranged on the second bonding portion corresponding to edges having the zigzag-shape.

8. The chip on film according to claim 1, wherein the second bonding portion comprises one or more first sub-portions, each of the first sub-portions is convex relative to the outer contour of the first bonding portion to form a protrusion, and some of the bonding terminals are arranged along one or more edges of the protrusion on the second bonding portion.

9. The chip on film according to claim 8, wherein a width of the protrusion is greater than a length of each of the bonding terminals.

10. The chip on film according to claim 8, wherein the protrusion is provided with one or more of the bonding terminals on each of opposite edges thereof.

11. The chip on film according to claim 1, wherein the second bonding portion comprises one or more first sub-portions, and the first sub-portions comprise one or more protrusions convex relative to the outer contour of the first bonding portion and one or more depressions concave relative to the outer contour of the first bonding portion.

12. The chip on film according to claim 9, wherein the second bonding portion comprises a plurality of first sub-portions, the plurality of first sub-portions comprises a plurality of protrusions convex relative to the outer contour of the first bonding portion and a plurality of depressions concave relative to the outer contour of the first bonding portion, the plurality of protrusions and the plurality of depressions are alternately arranged and connected along the outer contour of the first bonding portion, and a shape of outer edges of the plurality of first sub-portions is wavy.

13. The chip on film according to claim 1, wherein the base further comprises one or more hollow portions, the second bonding portion comprises one or more second sub-portions, and each of the second sub-portions comprises inner edges of the base surrounding one of the hollow portions.

14. The chip on film according to claim 13, wherein the base comprises a plurality of hollow portions, the plurality of hollow portions comprise a plurality of through holes, the second bonding portion comprises a plurality second sub-portions, each of the second sub-portions is arranged around one of the through holes, some of the bonding terminals are arranged around edges defining the through holes on the second sub-portions, the first bonding portion is arranged around the second sub-portions, and some of the bonding terminals are arranged on sides of the first bonding portion away from the second sub-portions.

15. The chip on film according to claim 14, wherein a distance between two adjacent ones of the through holes is greater than twice width of one of the bonding terminals.

16. A chip on film, comprising a display bonding area corresponding to bonding positions of a display panel, and comprising:
a base; and
bonding terminals, disposed on a side of the base,
wherein in the display bonding area, the base comprises a first bonding portion and a second bonding portion, and both of the first bonding portion and the second bonding portion are provided with the bonding terminals thereon;
the first bonding portion has an outer contour and comprises one part of outer edges of the base; and
the second bonding portion comprises one or more second sub-portions, the base further comprises one or more hollow portions, and each of the second sub-portions comprises inner edges of the base surrounding one of the hollow portions.

17. A display device, comprising:
a display panel, comprising signal terminals, and comprising:
a substrate; and
a driving circuit layer, disposed on a side of the substrate;
a chip on film, disposed on a side of the substrate away from the driving circuit layer, comprising a display bonding area corresponding to bonding positions of a display panel, and comprising:
a base; and
bonding terminals, disposed on a side of the base; and
conductive adhesives, connecting the signal terminals and the bonding terminals,
wherein in the display bonding area, the base comprises a first bonding portion and a second bonding portion, and both of the first bonding portion and the second bonding portion are provided with the bonding terminals thereon;
the first bonding portion has an outer contour and comprises one part of outer edges of the base; and
the second bonding portion comprises one or more first sub-portions, the first sub-portions comprises the other part of the outer edges of the base, and the first sub-portions are concave and/or convex relative to the outer contour of the first bonding portion.

18. The display device according to claim 17, further comprising insulation glues, wherein the insulation glues are disposed on sides of the conductive adhesives adjacent to the base.

19. The display device according to claim 18, wherein the insulation glues are arranged correspondingly to the conductive adhesives, and a width of each of the insulation glues is greater than a width of each of the conductive adhesives.

20. The display device according to claim 17, wherein the display panel includes a display area, a bending area, and a bonding area, an area of the chip on film is less than or equal to a sum of areas of the bending area and the bonding area, and the chip on film is bonded on the display panel and corresponds to the bending area and the bonding area.
